(19) United States
(12) Patent Application Publication
(10) Pub. No.: US 2013/0228364 A1
(43) Pub. Date: Sep. 5, 2013

(54) Method And System To Position Carbon Nanotubes Using AC Dielectrophoresis

(71) Applicants: Sarbajit Banerjee, Buffalo, NY (US); Irving P. Herman, Bronx, NY (US)

(72) Inventors: Sarbajit Banerjee, Buffalo, NY (US); Irving P. Herman, Bronx, NY (US)

(73) Assignee: The Trustees of Columbia University In The City Of New York, New York, NY (US)

(21) Appl. No.: 12/198,654

(22) Filed: Aug. 26, 2008

Related U.S. Application Data
(63) Continuation of application No. PCT/US2006/061807, filed on Dec. 8, 2006.
(60) Provisional application No. 60/781,573, filed on Mar. 10, 2006.

(51) Int. Cl. H05K 1/02; H05K 1/03; C25D 13/00

(52) U.S. Cl. CPC H05K 1/02; C25D 13/00; H05K 1/03; B82Y 30/00
USPC 174/255; 204/489; 204/622; 174/250; 977/882; 977/936

(57) ABSTRACT

A method for positioning carbon nanotubes on a substrate, the substrate including a first electrode and a second electrode thereon, the second electrode being positioned oppositely from the first electrode; the method includes: applying a first AC voltage across the first and second electrodes; providing a first resistance in series with the first AC voltage; and introducing a solution including at least one carbon nanotube; wherein, when the first AC voltage is applied through the first resistance across the first and second electrodes, the at least one carbon nanotube attaches to the first and second electrodes. Another aspect of the invention includes providing a metallic area between the first and second electrodes. In an additional aspect of the invention, the substrate includes a third electrode and a fourth electrode thereon, the fourth electrode being positioned oppositely from the third electrode, the third electrode being positioned adjacent to the first electrode; the method further includes: removing the first AC voltage; applying a second AC voltage to the third and fourth electrodes, the second AC voltage causing the first and second electrodes to have a floating potential; and providing a second resistance in series with the second AC voltage; wherein when the first AC voltage is applied across the first and second electrodes, the first AC voltage causes the third and fourth electrodes to have a floating potential, and wherein, when the second AC voltage is applied through the second resistance across the third and fourth electrodes, a second carbon nanotube attaches to the third and fourth electrodes.

### CROSS REFERENCE TO RELATED APPLICATION

This application is based on Provisional Application Ser. No. 60/781,573, filed Mar. 10, 2006, which is incorporated herein by reference for all purposes and from which priority is claimed.

### STATEMENT REGARDING FEDERALLY SPONSORED RESEARCH

The invention described herein was funded in part by grants from National Science Foundation Award No. CHE 0117752 and New York State Office of Science Technology and Academic Research, Award Number c030072. The United States Government may have certain rights under the invention.

### FIELD OF THE INVENTION

The present invention relates generally to carbon nanotubes and more particularly to positioning of carbon nanotubes by AC dielectrophoresis.

### BACKGROUND INFORMATION

Single-walled carbon nanotubes (SWNTs) have attracted much attention because of their unique size-dependent electrical and mechanical properties. Nanotubes have been shown to be very strong—e.g. the Young's modulus of a nanotube has been determined to be approximately 1.2 Tera pascals (more than six times that of steel). Nanotubes have also demonstrated remarkable electrical properties, such as resistance not increasing with length. However, to the present time, it has been challenging to arrange and/or orient carbon nanotubes within an electrical circuit.

The traditional Integrated Circuit (IC) fabrication process involves the deposition of films onto a wafer, followed by patterning-etching of the deposited films. As carbon nanotubes are different from films, they cannot be mass-produced in same manner. Accordingly, nanotubes have been assembled in device architectures in various ways including chemical modification of the substrate, direct growth on patterned substrates by chemical vapor deposition, and mechanical transfer protocol which involves the stamping of nanotubes onto a substrate.

Some prior art discloses the deposition of nanotubes between vertical DC potential electrode plates from an electrophoresis bath to form upright arrays of nanotubes for field emission. Other prior art techniques are directed to trapping nanoscale objects by using alternating-current voltages between electrodes.

Unfortunately, control over the number of nanotubes which are deposited between lateral electrodes using the prior art methods is difficult. In addition, spatial resolution (particularly in 3D) is not easily attained. Moreover, the prior art techniques can be difficult or impossible to apply to more complex device structures, such as multi-terminal transistors and branching interconnects.

Accordingly, a need exists in the art for a controllable technique to deposit and align structures of carbon nanotube-based devices and interconnections.

### SUMMARY OF THE INVENTION

The present invention provides methods and apparatuses for the controlled deposition and alignment of carbon nanotubes. The present invention can thus facilitate the fabrication of nanotube-based devices and interconnects.

One embodiment of the present invention provides a method of positioning carbon nanotubes on a substrate, the substrate including a first electrode and a second electrode thereon; the method includes: applying a first AC voltage across the first and second electrodes; providing a first resistance in series with the first AC voltage; and introducing a solution including at least one carbon nanotube; wherein, when the first AC voltage is applied through the first resistance across the first and second electrodes, the at least one carbon nanotube attaches to the first and second electrodes.

An exemplary embodiment of the present invention provides a method of positioning carbon nanotubes on a substrate, the substrate including a first electrode and a second electrode thereon, the substrate further including a third electrode and a fourth electrode thereon, the third electrode being positioned adjacent to the first electrode; the method includes: applying a first AC voltage across the first and second electrodes; providing a first resistance in series with the first AC voltage; and introducing a solution including at least one carbon nanotube; wherein, when the first AC voltage is applied through the first resistance across the first and second electrodes, the at least one carbon nanotube attaches to the first and second electrodes, and when the first AC voltage is applied across the first and second electrodes, the first AC voltage causes the third and fourth electrodes to have a floating potential.

An exemplary embodiment of the present invention provides a method of positioning carbon nanotubes on a substrate, the substrate including a first electrode and a second electrode thereon, the substrate further including a third electrode and a fourth electrode thereon, the third electrode being positioned adjacent to the first electrode; the method includes: applying a first AC voltage across the first and second electrodes; providing a first resistance in series with the first AC voltage; and introducing a solution including at least one carbon nanotube; removing the first AC voltage; applying a second AC voltage to the third and fourth electrodes, the second AC voltage causing the first and second electrodes to have a floating potential; and providing a second resistance in series with the second AC voltage; wherein, when the first AC voltage is applied through the first resistance across the first and second electrodes, the at least one carbon nanotube attaches to the first and second electrodes, and when the first AC voltage is applied across the first and second, electrodes, the first AC voltage causes the third and fourth electrodes to have a floating potential; wherein, when the second AC voltage is applied through the second resistance across the third and fourth electrodes, a second carbon nanotube attaches to the third and fourth electrodes.

An exemplary embodiment of the present invention provides a method of positioning carbon nanotubes on a substrate, the substrate including a first electrode and a second electrode thereon, the substrate further including a third electrode and a fourth electrode thereon, the third electrode being positioned adjacent to the first electrode, the substrate further including a metallic area thereon between the first and second electrodes, the metallic area being capable of perturbing an electric field formed by the first AC voltage source; the method includes: applying a first AC voltage across the first and second electrodes; providing a first resistance in series with the first AC voltage; and introducing a solution including at least one carbon nanotube; wherein, when the first AC voltage is applied through the first resistance across the first and second electrodes, the at least one carbon nanotube attaches to the first and second electrodes, and when the first AC voltage is applied across the first and second electrodes, the first AC voltage causes the third and fourth electrodes to have a floating potential.

In yet another exemplary embodiment of the present invention, a circuit element coupled to the substrate is made by the any of the aforementioned exemplary processes.

Another embodiment of the present invention provides a system for positioning carbon nanotubes on a substrate, the substrate including a first electrode and a second electrode thereon; the system including: a base for receiving the substrate; a first AC voltage source coupled to the base, the first AC voltage source for applying a first AC voltage across the first and second electrodes; and a first resistor coupled to the first AC voltage source to provide a first resistance in series with the first AC voltage source; wherein, when the first AC voltage is applied through the first resistor across the first and second electrodes and a solution including at least one carbon nanotube is introduced on the substrate between the electrodes, the at least one carbon nanotube attaches to the first and second electrodes.

An exemplary embodiment of the present invention provides a system for positioning carbon nanotubes on a substrate, the substrate including a first electrode and a second electrode thereon, the substrate further including a third electrode and a fourth electrode thereon, the third electrode being positioned adjacent to the first electrode; the system including: a base for receiving the substrate; a first AC voltage source coupled to the base, the first AC voltage source for applying a first AC voltage across the first and second electrodes; and a first resistor coupled to the first AC voltage source to provide a first resistance in series with the first AC voltage source; wherein, when the first AC voltage is applied through the first resistor across the first and second electrodes and a solution including at least one carbon nanotube is introduced on the substrate between the electrodes, the at least one carbon nanotube attaches to the first and second electrodes and the first AC voltage causes the third and fourth electrodes to have a floating potential.

An exemplary embodiment of the present invention provides a system for positioning carbon nanotubes on a substrate, the substrate including a first electrode and a second electrode thereon, the substrate further including a third electrode and a fourth electrode thereon, the third electrode being positioned adjacent to the first electrode; the system including: a base for receiving the substrate; a first AC voltage source coupled to the base, the first AC voltage source for applying a first AC voltage across the first and second electrodes; and a first resistor coupled to the first AC voltage source to provide a first resistance in series with the first AC voltage source; a second AC source coupled to the base, the second AC source for applying a second AC voltage to the third and fourth electrodes, the second AC voltage causing the first and second electrodes to have a floating potential; and a second resistor coupled to the second AC source to provide a second resistance in series with the second AC voltage; wherein, when the first AC voltage is applied through the first resistor across the first and second electrodes and a solution including at least one carbon nanotube is introduced on the substrate between the electrodes, the at least one carbon nanotube attaches to the first and second electrodes and the first AC voltage causes the third and fourth electrodes to have a floating potential; wherein, when the second AC voltage is applied through the second resistor across the third and fourth electrodes, a second carbon nanotube attaches to the third and fourth electrodes.

An exemplary embodiment of the present invention provides a system for positioning carbon nanotubes on a substrate, the substrate including a first electrode and a second electrode thereon, the substrate further including a third electrode and a fourth electrode thereon, the third electrode being positioned adjacent to the first electrode; the substrate further including a metallic area thereon between the first and second electrodes, the metallic area being capable of perturbing an electric field formed by a first AC voltage source, the system including: a base for receiving the substrate; the first AC voltage source coupled to the base, the first AC voltage source for applying a first AC voltage across the first and second electrodes; and a first resistor coupled to the first AC voltage source to provide a first resistance in series with the first AC voltage source; wherein, when the first AC voltage is applied through the first resistor across the first and second electrodes and a solution including at least one carbon nanotube is introduced on the substrate between the electrodes, the at least one carbon nanotube attaches to the first and second electrodes and the first AC voltage causes the third and fourth electrodes to have a floating potential.

In yet another exemplary embodiment of the present invention, the first and second electrodes used in any of the aforementioned embodiments include approximately pointed geometries. As used herein, an example of “approximately pointed geometry” is where the tip of the electrode is significantly narrower than the base thereof. Thus, the electrode tip may be round, blunt, or sharp and still constitute “an approximately pointed geometry.”

In another exemplary embodiment of the present invention, the third and fourth electrodes used in any of the aforementioned embodiments include approximately pointed geometries.

In accordance with an aspect of the present invention, the invention includes AC dielectrophoresis of SWNTs to build devices using pre-patterned microelectrodes.

The controllable placement of SWNTs in device architectures may be achieved by enhancement of one or more of electrode geometry, voltage, time and frequency of the applied voltage, load resistance, and type of nanotube sample used.

For example, an arrangement may include electrodes with a pointed geometry to controllably position carbon nanotubes on a substrate.

The arrangement may also include four electrodes, the voltage being applied across two opposite electrodes with the other two floating.

In accordance with an aspect of the present invention, an arrangement includes a resistor connected in series with the voltage in order to control the number of nanotubes deposited on the substrate.

In accordance with an aspect of the present invention, AC voltages are used to align micelle-wrapped nanotubes based on the dielectric constants of the nanotubes without any extraneous additives to charge the nanotubes. Surface charges due to surfactant wrapping may however affect the dielectrophoretic deposition process. The nanotubes may be deposited on lateral electrodes patterned on a substrate. Surface modifications to the electrodes tend not to be necessary in order to make them adhere to make them adhere to the substrate.

### BRIEF DESCRIPTION OF THE DRAWINGS

FIG. 1 is a diagram of the interacting components of a system according to an exemplary embodiment of the present invention.

FIG. 2 is a diagram illustrating an exemplary process whereby nanotubes may be positioned using the system of FIG. 1.

FIG. 3 is a diagram illustrating an exemplary process for obtaining SWNTs in aqueous solution.

FIG. 4(a) is a scanning electron microscopy (SEM) image of a pair of electrodes with sodium dodecylbenzene sulfonate (NaDDBS) wrapped SWNTs attached therebetween demonstrating the effect of an 8 Volt, 5 MHz, AC voltage for 120 seconds between the pair of electrodes of an exemplary arrangement according to the present invention.

FIG. 4(b) is an SEM image of a pair of electrodes with poly(maleic acid/octyl vinyl ether) (PMAOVE) wrapped SWNTs attached therebetween demonstrating the effect of an 8 Volt, 5 MHz, AC voltage for 120 seconds between the pair of electrodes of an exemplary arrangement according to the present invention.

FIG. 4(c) is an SEM image of the exemplary embodiment of FIG. 4(a), but with a 44 M ohm resistor in series with the voltage applied across the electrodes.

FIG. 4(d) is an SEM image of the exemplary embodiment of FIG. 4(b), but with a 76 M ohm resistor in series with the voltage applied across to the electrodes.

FIG. 4(e) is an SEM image of a pair of pointed opposite electrodes and an adjacent pair of floating electrodes with NaDDBS wrapped SWNTs attached between the pair of opposite electrodes demonstrating the effect of an 8 Volt, 5 MHz, AC voltage for 120 seconds between the pair of pointed opposite electrodes of an exemplary embodiment according to the present invention.

FIG. 4(f) is an SEM image of the exemplary electrode arrangement of FIG. 4(e), but with a 1 G ohm resistor in series with the voltage applied across to the electrodes.

FIG. 5(a) is an SEM image of a first and second electrodes and an adjacent pair of floating electrodes with SWNTs attached between the first electrode and each of the adjacent electrodes demonstrating the effect of an 8 Volt, 5 MHz, AC voltage on this circuit arrangement.

FIG. 5(b) is a graph showing calculated electric field magnitude for 10 micrometer gap electrodes of the same electrode geometry of FIG. 5(a).

FIG. 5(c) is an SEM image of a pair of opposite electrodes with 500 nanometer diameter metal posts patterned therebetween, and an adjacent pair of floating electrodes, with SWNTs attached between the pair of opposite electrodes demonstrating the effect of an 8 Volt, 5 MHz, AC voltage between the pair of opposite electrodes of an exemplary embodiment according to the present invention.

FIG. 5(d) is a graph showing calculated electric field magnitude for the electrode geometry of FIG. 5(c).

FIG. 5(e) is an SEM image of a pair of opposite electrodes with 300 nanometer diameter metal posts patterned therebetween, and an adjacent pair of floating electrodes, with SWNTs attached between the pair of opposite electrodes demonstrating the effect of an 8 Volt, 5 MHz, AC voltage between the pair of opposite electrodes of an exemplary embodiment according to the present invention.

FIG. 5(f) is an SEM image of a pair of opposite electrodes with 1 micrometer wide metal strips patterned therebetween, and an adjacent pair of floating electrodes, with a single SWNT attached between the pair of opposite electrodes along the strips demonstrating the effect of an 8 Volt, 5 MHz, AC voltage between the pair of opposite electrodes of an exemplary embodiment according to the present invention.

FIG. 6(a) is an SEM image of a first and second 1 micrometer wide electrodes and an adjacent pair of 1 micrometer wide floating electrodes with NaDDBS wrapped SWNTs attached between the first electrode and each of the adjacent electrodes, the second electrode and each of the adjacent electrodes, and the first and second electrode demonstrating the effect of an 8 Volt, 5 MHz, AC on this circuit arrangement.

FIG. 6(b) is an SEM image of a pair of pointed opposite electrodes and an adjacent pair of pointed floating electrodes with an SWNT attached between the pair of opposite electrodes demonstrating the effect of an 6.5 Volt, 5 MHz, AC voltage between the pair of pointed opposite electrodes of an exemplary embodiment according to the present invention.

FIG. 6(c) is an SEM image of a crossed nanotube junction of an exemplary embodiment according to the present invention.

FIG. 6(d) is an SEM image of a crossed nanotube junction of an exemplary embodiment according to the present invention.

FIGS. 6(e) and 6(f) are SEM images showing the formation of a crossed nanotube junction of an exemplary embodiment according to the present invention.

FIG. 7(a)(iii) is an SEM image of a pair of opposite electrodes with metal posts patterned therebetween, and an adjacent pair of floating electrodes, with SWNTs attached between the pair of opposite electrodes of an exemplary embodiment according to the present invention.

FIG. 7(a)(i) is a graph showing the Current v. Voltage (I-V) characteristics of SWNT devices assembled FIG. 7(a)(iii).

FIG. 7(a)(ii) is a graph showing the I-V characteristics of SWNT devices assembled FIG. 7(a)(iii), after heating.

FIG. 7(b)(iii) is an SEM image of a pair of opposite electrodes and an adjacent pair of floating electrodes, with SWNTs attached between the pair of opposite electrodes of an exemplary embodiment according to the present invention.

FIG. 7(b)(i) is a graph showing the I-V characteristics of SWNT devices assembled FIG. 7(b)(iii).

FIG. 7(b)(ii) is a graph showing the I-V characteristics of SWNT devices assembled FIG. 7(b)(iii), after heating.

Moreover, while the present invention will now be described in detail with reference to the figures, it is done so in connection with the illustrative embodiments.

### DETAILED DESCRIPTION

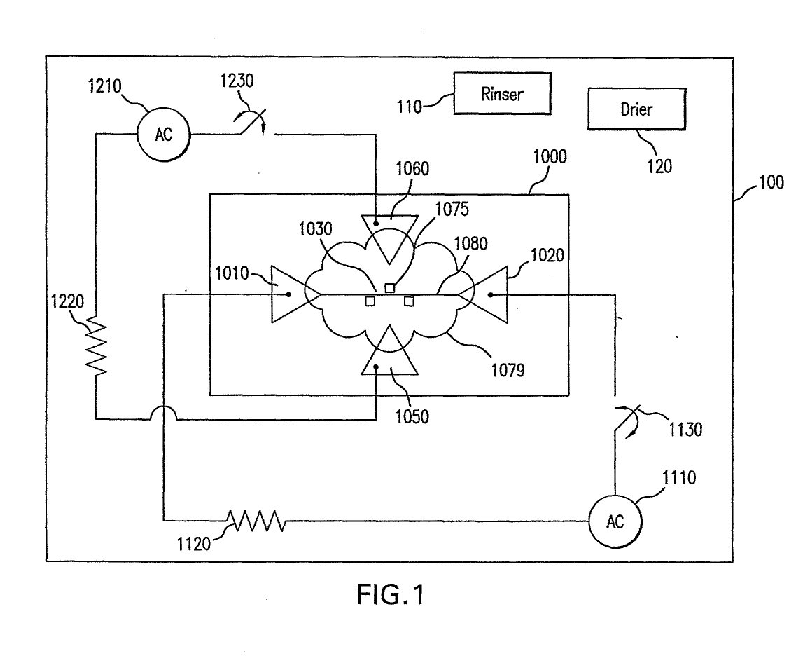

FIG. 1 is a block diagram of the components of a system according to one exemplary embodiment of the present invention. The system includes a base 100 for receiving a substrate 1000. The substrate 1000 may be formed of SiO₂ (500 nanometer)/Si. Any gate dielectric surface may be used instead of SiO₂, examples include 1) silicon nitride Si₃N₄ 2) hafnia HfO₂, 3) zirconia ZrO₂, 4) alumina Al₂O₃, 5) glass, or 6) plastic. The thicknesses can range from 5 nanometer to 1 micrometer. Alternatives for silicon include indium tin oxide (ITO) or any metallic surface. The substrate 1000 includes a first electrode 1010 and a second electrode 1020 which may be patterned thereon by electron beam lithography or optical lithography, followed by thermal or electron beam evaporation of Cr/Au electrodes. Any relatively inert metal electrodes may be used including gold, platinum, palladium, gold-palladium alloys, indium, etc. The thickness of the electrodes may range from 50-250 nanometers. Between the first 1010 and second 1020 electrodes, there is a gap 1030. In an optional arrangement, metallic areas 1075 may be patterned on the substrate 1000 in the gap 1030. The gap 1030 may range from 15 nanometers to 20 micrometers; metallic areas 1075 may range from 200 nanometers to 1 micrometer in diameter. The substrate may also include a third electrode 1050 and a fourth electrode 1060 which may be patterned thereon by electron beam lithography or optical lithography, followed by thermal or electron beam evaporation of Cr/Au electrodes. An AC voltage source 1110 coupled in series with a resistor 1120 is used to create an electric field between the first electrode 1010 and the second electrode. The voltage of the source may range from approximately 6-8 volts (peak to peak) Voltage that is to be applied depends on the gap distance; typical range is about 0.5-1.0 V per micrometer of the gap. The frequency of the AC source may be approximately 5 MHz, and the voltage may be switched on and off by way of a switch 1130 or suitable means. A further AC voltage source 1210 coupled in series with a further resistor 1220 may be used to create a further electric field between the third electrode 1050 and the fourth electrode 1060. The further voltage may be switched on and off by way of a further switch 1230 or suitable means.

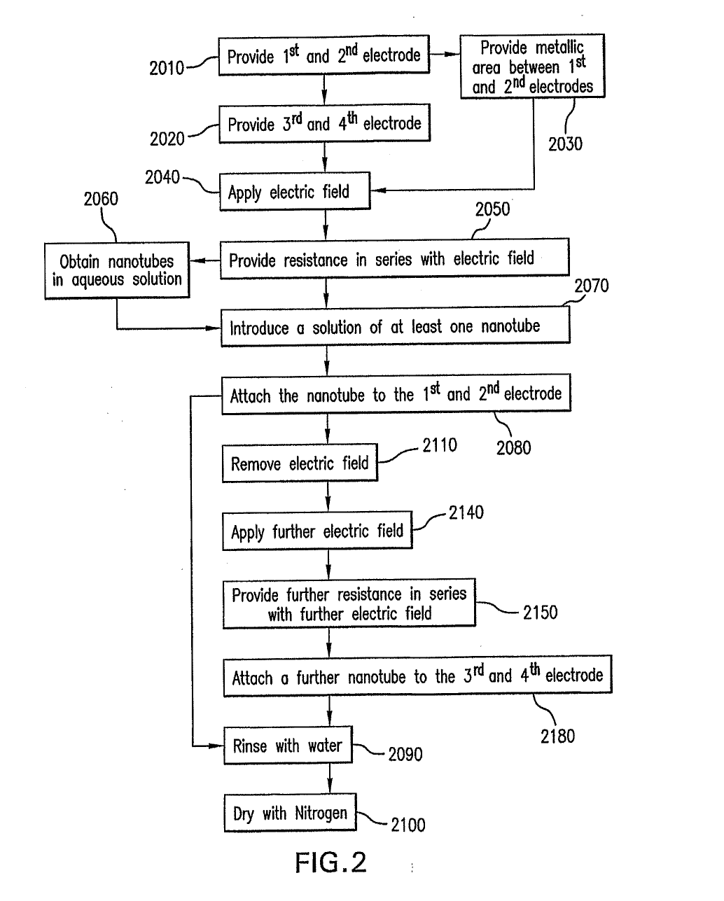

FIG. 2 is a diagram illustrating an exemplary procedure whereby nanotubes may be positioned using the system of FIG. 1. A first 1010 and a second 1020 electrode may be provided (2010). A third 1050 and fourth electrode 1060 may also be provided on the substrate 1000 (2020). Optionally, a metallic area 1075 between the first 1010 and second 1020 electrodes may be provided on the substrate 1000 (2030). The metallic area may be comprised of any relatively inert metals: gold, palladium, platinum, gold-palladium alloy, etc. A voltage may be applied across the first 1010 and second 1020 electrodes by an AC voltage source 1110 (2040), which may be coupled in series with a resistor 1120 while the voltage is applied (2050).

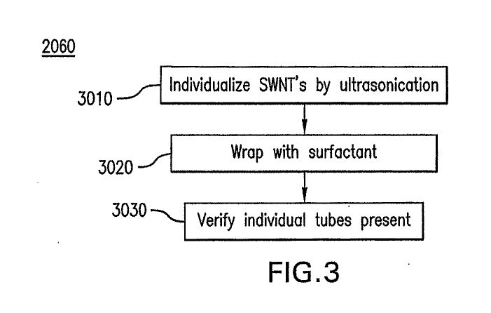

FIG. 3 depicts an exemplary technique for obtaining SWNTs in aqueous solution (2060). The availability of micelle-solubilized nanotubes has made it possible to obtain single SWNTs in aqueous solution, which allows for greater control over the dielectrophoretic assembly process. HiPCO SWNTs made by the catalytic decomposition of CO (Carbon Nanotechnologies), and CoMoCAT nanotubes made by the chemical vapor deposition over silica-supported Co and Mo catalysts (produced by Southwest Nanotechnologies) may be individualized by ultrasonication (3010). The individual nanotubes may then be dispersed in aqueous solution by wrapping with a surfactant (3020). Too much ultrasonication may result in nanotubes that are too short to span the gap between opposing electrodes. For a given gap of 3 micrometers, for example, the nanotubes should be at least of this length in order to span the gap between the electrodes. For larger gaps, for example 10 micrometers, the nanotubes should be at least of this length in order to span the gap. As stated above, typical ranges for the gap are between 15 nanometers to 20 micrometers. Thus, the duration of the ultrasonication process may effect the length of the tubes. The micelle molecules are quasi-spherical and range in diameter from 5-8 nm in solution. The wrapping micelles may be sodium dodecylbenzene sulfonate (NaDDBS), sodium dodecyl sulfate (SDS), poly(maleic acid/octyl vinyl ether) (PMAOVE), or sodium bis-2-ethylhexyl-sulfosuccinate (AOT). Using UV-VIS-NIR absorption and photoluminescence spectra, it can be shown that the tubes wrapped in these micelles were predominately individual tubes (3030). The length and concentration of the tubes may be controlled by the duration of the sonication process.

Referring back to FIG. 2, the nanotube dispersion in aqueous solution 1079 may be placed on the substrate 1000 (2070). A micropipette may be used to apply a few microliters in the electrode gap. The volume of the solution may be an approximately 8 microliter drop. The typical volume applied would be between 5 microliters to 100 microliters. The nanotube dispersion may be held in the gap 1030 between the electrodes 1010, 1020 for approximately 30 to 300 seconds, during which the AC voltage is applied (2050) between first 1010 and second 1020 electrodes, with the third 1050 and fourth 1060 electrodes having a floating potential. The voltage is typically turned on first; the drop is simply held by surface tension on the substrate 1000. A nanotube 1080 then attaches to the first 1010 and second 1020 electrode (2080). Optionally, the substrate 1000 may then be rinsed with deionized water (2090) with a rinsor 110 (in FIG. 1) and dried in nitrogen (2100) with a drier 120 (in FIG. 1). Rinsing helps to wash away all the nanotubes that are not aligned between the electrodes. Drying removes water so that the devices may be we electrically tested for transistor performance.

Dielectrophoresis is based on the following principle: when a particle in a medium has a higher effective dielectric constant (which includes the real dielectric constant and conductivity terms) than the medium, it experiences a positive dielectrophoretic force that brings it into the higher electric field region. The dielectric force originates from the interaction between the non-uniform electric field and the induced dipole in the dielectric particle.

Optionally, after the nanotube 1080 is attached (2080), the voltage applied across the first 1010 and second 1020 electrode may be removed (2110). A further voltage may applied across the third 1050 and fourth 1060 electrodes by an AC voltage source 1210 (2140), which may be coupled in series with a resistor 1220 while the further voltage is applied (2150). A further nanotube is then attached between the third 1050 and fourth 1060 electrodes (2180). The substrate 1000 is then rinsed with deionized water (2090) and dried in nitrogen (2100).

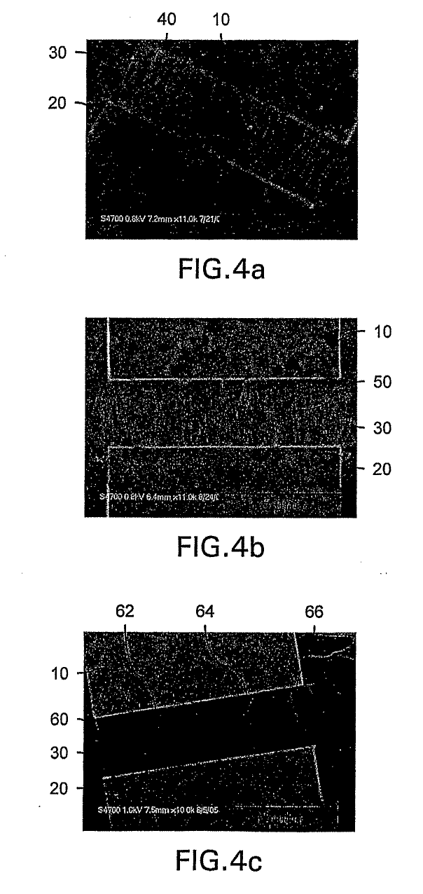

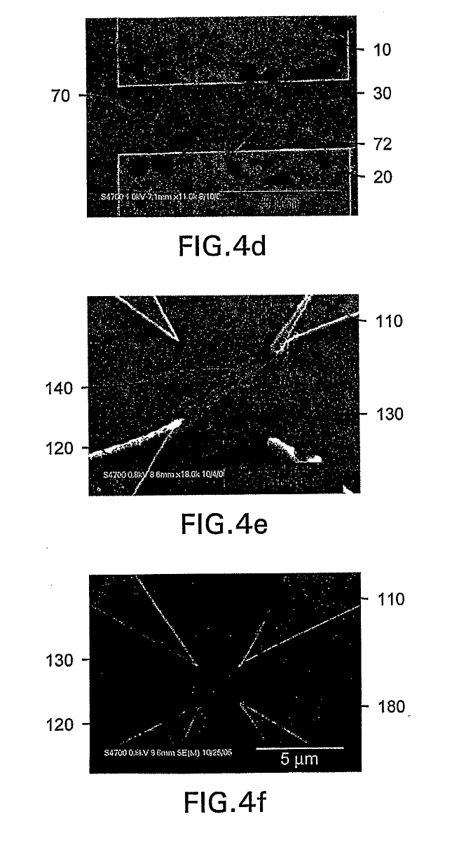

FIGS. 4(a)-(f), 5(a), 5(c), 5(e)-(f), 6(a)-(f), 7(a)(iii), and 7(b)(iii) are scanning electron microscopy (SEM) images taken using a Hitachi S4700 operated at 0.8-1 kV with a working distance of 6-12 mm.

FIGS. 4(a)-(d) demonstrate the effect of an 6-8 Volt, 5 MHz AC voltage across an opposite pair of rectangular electrodes for 120 seconds. The width of the electrodes 10, 20 is 10 micrometers, and the gap 30 between them measures 3 micrometers.

FIGS. 4(a) and 4(b) depict certain components of an arrangement according to exemplary embodiments of the present invention. In FIG. 4(a), NaDDBS wrapped SWNTs 40 are shown aligned in the gap 30. In FIG. 4(b), PMAOVE-wrapped HiPCO SWNTs 50 are shown aligned in the gap 30. Such nanotube network devices may be useful for certain applications, such as flexible electronics and sensors.

Many applications, however, require discrete devices based on single nanotubes, and thus controlling the number of nanotubes deposited in the gap 30 is important. This may be achieved to some extent by controlling the time the AC voltage is applied. The voltages applied depends on the gap distance; typically about 0.5-1 Volt is needed per micrometer of the gap. For a given gap distance and voltage, the voltage is applied for times ranging from 1 s to 600 s. More effective control over the number of nanotubes deposited may be accomplished however by placing a limiting resistor (not shown in FIGS. 4(a)-(d)) in series with the AC voltage source. The limiting resistor is chosen based on the resistance at the contacts between the nanotubes and the electrodes (the contact resistance). Limiting resistors typically from 22 mega-ohms to 4 giga-ohms are used. In this respect, when a single nanotube or nanotube bundle bridges the gap 30, the limiting resistor effectively shuts off the voltage, preventing any further dielectrophoretic trapping of SWNTs. The nanotubes should be long enough to span the gap. The length of the nanotubes can be controlled by the sonication time.

FIG. 4(c) depicts certain components of an arrangement according to an exemplary embodiment of the present invention. FIG. 4(c) shows the effect of certain resistances in conjunction with the conditions of FIGS. 4(a). In FIG. 4(c), four NaDDBS-wrapped SWNT bundles 60, 62, 64, 66 are shown aligned in the gap 30 under the same conditions as in FIG. 4(a), but with a 44 M ohm limiting resistor (not shown in FIG. 4(c)) in series with the circuit.

FIG. 4(d) depicts certain components of an arrangement according to an additional exemplary embodiment of the present invention. FIG. 4(d) show the effect of certain resistances in conjunction with the conditions of FIG. 4(b). In FIG. 4(d), two NaDDBS-wrapped HiPCO SWNT bundles 70, 72 are shown aligned in the gap 30 under the same conditions as in FIG. 4(a), but with a 76 M ohm limiting resistor (not shown in FIG. 4(d)) in series with the circuit.

FIGS. 4(e) and 4(f) depict certain components of arrangements according to additional exemplary embodiments of the present invention. FIG. 4(e)-(f) demonstrate the effect of an 6.5 Volt, 5 MHz AC voltage across an opposite pair of pointed electrodes 110,120 for 120 seconds. The gap 130 between them measures 3 micrometers. In FIG. 4(e), NaDDBS wrapped HiPCO SWNTs 140 are shown aligned in the gap 130 between pointed electrodes 110, 120. In FIG. 4(f), one NaDDBS-wrapped HiPCO SWNT bundle 180 is shown aligned in the gap 130 under the same conditions as in FIG. 4(e), but with a 1 G ohm limiting resistor (not shown in FIG. 4(f)) in series with the circuit.

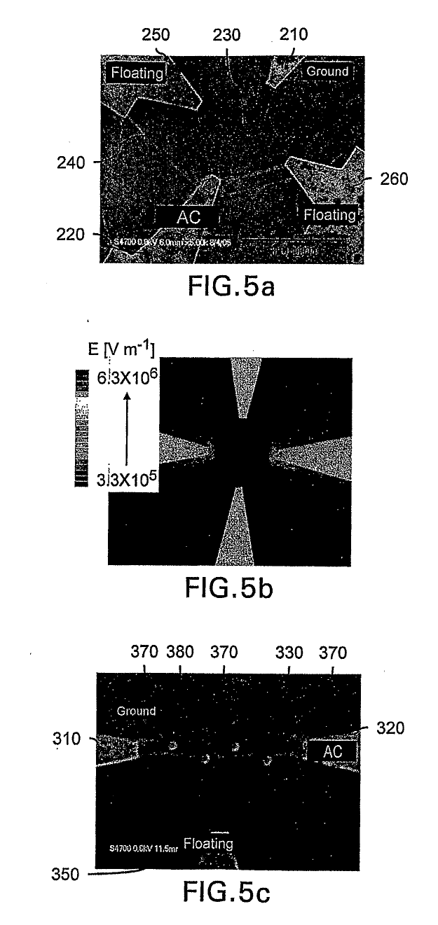

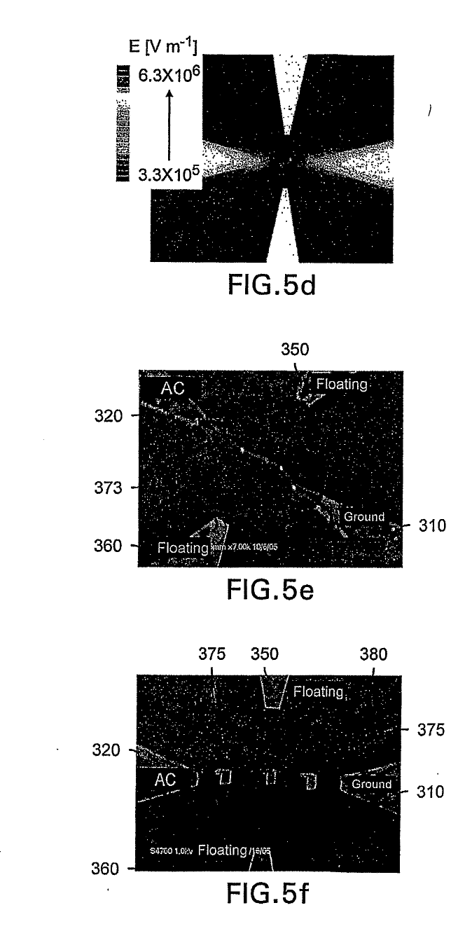

FIG. 5(a) depicts the potentially undesired effect when four symmetric electrodes are used and a voltage is applied across opposite electrodes 210, 220, the nanotubes 240 tend to span adjacent electrodes 250, 260 (depending on among other things the electrode geometry), which have a floating potential. The gap 230 in FIG. 5(a) between electrodes 210, 220 measures 10 micrometers. FIG. 5(b) shows the calculated electric field for the geometry indicated in FIG. 5(a). The electric field profile was simulated by finite element analysis using Maxwell 3D software from Ansoft Corporation.

One way to alleviate the problem of the nanotubes spanning to adjacent floating electrons is to pattern metal posts 370 or strips within the gap 330 (see FIG. 5(c)). FIG. 5(c) depicts certain components of an arrangement according to an additional exemplary embodiment of the present invention. Patterned metal posts 370 or strips within the gap 330 perturb the electric field. As shown in FIG. 5(d), the posts 370 or strips lead to regions where the electric field is locally enhanced, relative to the simulation depicted in FIG. 5(b). The posts 370 or strips in FIG. 5(c) assist in guiding nanotubes 380 along a predictable path. FIG. 5(c) depicts nanotube alignment between the posts 370. In FIG. 5(c), the posts 370 have a diameter of about 500 nanometers. FIG. 5(e) depicts an arrangement according to an alternative exemplary embodiment of the present invention. FIG. 5(e) is similar to FIG. 5(c), but depicts nanotube alignment in a “zigzag” pattern. In FIG. 5(e), the posts 373 have a diameter of 300 nanometers. FIG. 5(f) depicts certain components of an arrangement according to another exemplary embodiment of the present invention. FIG. 5(f) depicts nanotube alignment with the tubes 380 touching the metal strips 375. Without the application of a voltage, there is no alignment of nanotubes. In FIGS. 5(c), 5(e), and 5(f), an 8 Volt, 5 MHz voltage was applied, and the width of the electrodes 310, 320, 350, 360 measures 1 micrometer. Such dielectrophoretically positioned metallic tubes may be particular useful for fabricating complex multi-terminal interconnects.

AC dielectrophoresis may also be used to build other complex geometries, such as crossed nanotube junctions which may potentially be useful for applications such as nonvolatile random access memory. The crossing between two semiconducting or two metallic tubes has been seen to behave as a tunnel junction, whereas junctions between a metallic and a semiconducting tube have shown Schottky diode-like behavior. An embodiment of the present invention may be used to controllably assemble crossed nanotube junctions within device architectures.

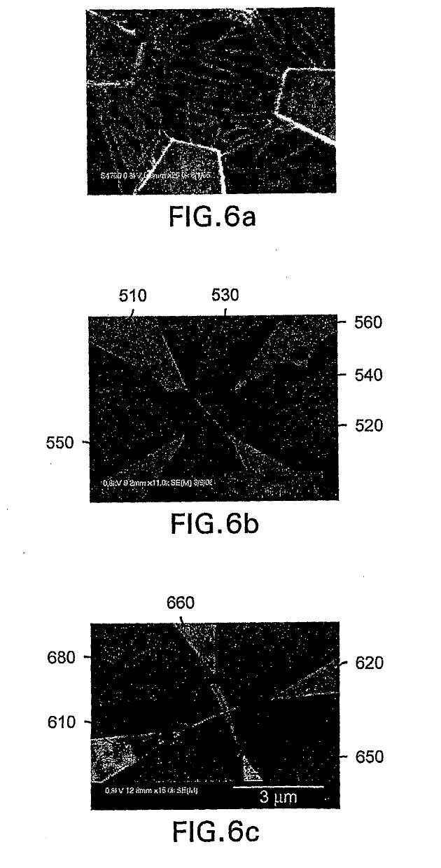

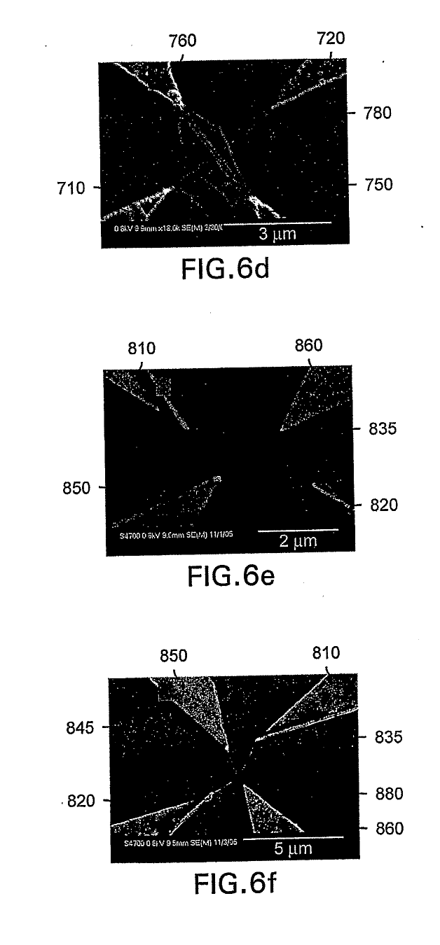

A challenge to assembling crossed nanotube structures by AC dielectrophoresis is that the nanotubes tend to span to adjacent floating electrodes, as depicted in FIG. 5(a) discussed above. FIG. 6(a) illustrates this similarly. One approach to alleviate this problem was discussed above—by using the floating potential metal posts or strips, as depicted in FIGS. 5(c), 5(e), and 5(f). An alternate approach is to modify the geometry of the electrodes.

FIG. 6(b) depicts certain components of an arrangement according to another exemplary embodiment of the present invention. The arrangement includes pointed electrodes 510, 520, through which a voltage is applied. The arrangement also includes pointed electrodes 550, 560, which have a floating potential. Keeping the gap 530 at a constant value (30 micrometers), the distance between adjacent electrodes in FIG. 6(b) as compared to FIG. 6(a) is increased (from 1.41 micrometers in FIGS. 6(a) to 2.12 micrometers in FIG. 6(b) with the use of pointed electrodes 510, 520, 550, 560). This increase in distance reduces the likelihood that tubes will span to the floating electrodes 550, 560. The pointed electrode 510, 520 geometry on its own may not be sufficient to prevent SWNTs from aligning to a floating side electrode 550, 560. When 8 Volts is applied across the opposite pair of electrodes 510, 520, the field in the middle 1 micrometer of the 3 micrometer gap ranges from 1.08×10⁶ to 1.25×10⁶ V/m. This may be allow some nanotubes to be trapped across the adjacent floating 550, 560, and opposite powered electrodes 510, 520.

At a low enough voltage (6.5 Volts), however, the tubes align across opposite powered electrodes 510, 520 and not between adjacent powered 510, 520 and floating electrodes 550, 560. As such, a combination of voltage control and/or pointed electrode geometries may enable reproducible and controllable fabrication of complex circuits. Thus, the formation of a nanotube from electrode A to electrode B, while still in the presence of other electrodes C and D, can be achieved for more complex circuits such as multiterminal devices.

FIG. 6(c) depicts a crossed-nanotube junction 680 obtained by sequentially applying a 6.5 Volt, 5 MHz voltage across opposite pairs of electrodes 510, 520, 550, 560. This junction 680 was fabricated from NaDDBS-wrapped HiPCO tubes.

FIG. 6(d) depicts a crossed-nanotube junction 780 obtained by sequentially applying a 6.5 Volt, 5 MHz voltage across opposite pairs of electrodes 610, 620, 650, 660 for 120 seconds. This junction 780 was fabricated from NaDDBS-wrapped CoMo CAT nanotubes.

FIGS. 6(e) and 6(f) depict certain components of an arrangement according to another embodiment of the present invention. In FIGS. 6(e) and 6(f), a crossed junction 880 of two HiPCO nanotubes 835, 845 was obtained by applying a 6.5 Volt AC voltage in series with a 1 G ohm resistance across one opposite pair of electrodes 810, 820 with adjacent electrodes 850, 860 floating (in FIG. 6(e)), and then across the other opposite pair of electrodes 850, 860 with adjacent electrodes 810, 820 floating (in FIG. 6(f)). Thus, by combining electrode design, voltage control (which controls the location of tube placement), and/or the use of limiting series resistors (which limits the number of tubes deposited), the fabrication of crossed nanotube structures with a single tube across each pair of opposite electrodes is now possible. For 3 micrometer gaps, voltages between 6-7 Volts typically are typically preferred; the voltages should be appropriately scaled for smaller or larger gaps. Use of voltages which are too high may lead to the nanotubes going across to the side electrodes. The use of pointed electrodes enables nanotubes to span opposite electrodes without aligning across the adjacent electrodes. The limiting resistor enables a single nanotube to be deposited in the gap.

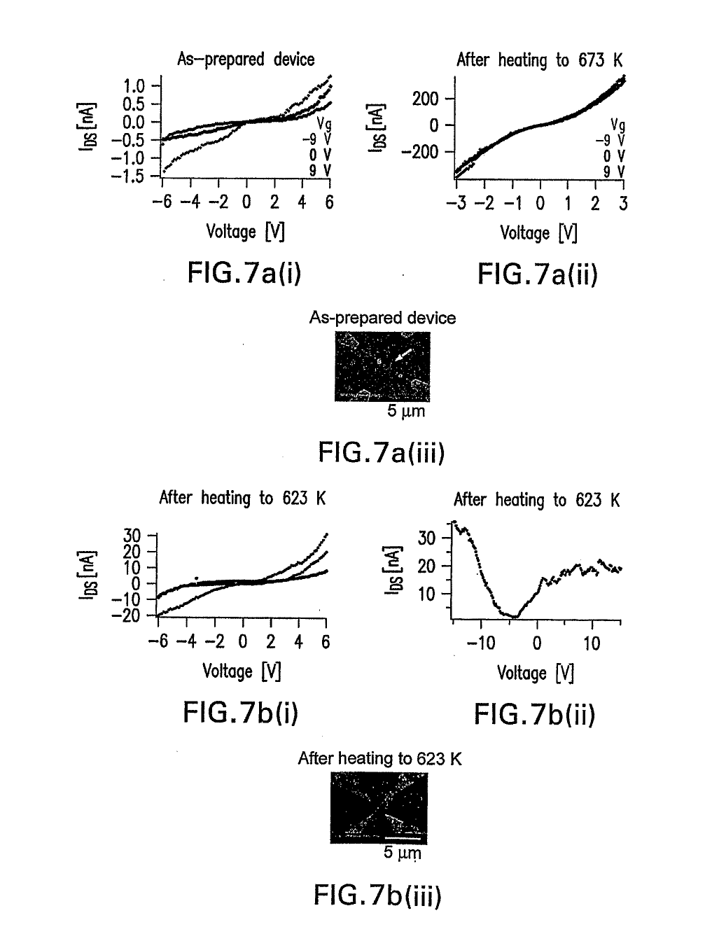

FIG. 7(a)(iii) is an SEM image of a pair of opposite electrodes with metal posts patterned therebetween, and an adjacent pair of floating electrodes, with SWNTs attached between the pair of opposite electrodes. FIG. 7(b)(iii) is an SEM image of a pair of opposite electrodes and an adjacent pair of floating electrodes, with SWNTs attached between the pair of opposite electrodes. The dielectrophoretically deposited devices of FIGS. 7(a)(iii) and 7(b)(iii) demonstrate a relatively high contact resistance, ranging from 500 M ohms to 1 G ohm for NaDDBS wrapped samples.

FIGS. 7(a)(i)-(ii) and 7(b)(i)-(ii) are graphs showing pronounced gate dependence and occasionally exhibit significant asymmetry. The I-V curves of FIGS. 7(a)(i)-(ii) and 7(b)(i)-(ii) were obtained on a HP4145 semiconductor parameter analyzer. The gate dependence and asymmetry are likely due to the surfactant molecules forming a tunneling barrier at the contact. The tethering of the tubes at the two electrodes may vary significantly depending on the surfactant coverage, presence of solvent at the contact, and the contact area. The contact resistance may be greatly reduced by annealing under at N₂ atmosphere at 350° C. 400° C. for 10 minutes. The PMAOVE samples seem to have a much higher contact resistance—on the order of 10-20 G ohms, which may be due to the better stacking and association of the polymer to the nanotube sidewalls.

The HiPCO samples used to generate the SEM images of FIGS. 4-7 ranged from 0.8-1.3 nm in diameter and showed a wide distribution of chiralities, with approximately one-third of the SWNTs expected to be metallic based on a random distribution of nanotube chiralities. The CoMoCAT SWNTs were enriched (6,5) and (7,5) semiconducting nanotubes and there were eleven times as many semiconducting tubes as metallic tubes. (For a given (n,m) nanotube, if 2n+m=3q (where q is an integer), then the nanotube is metallic, otherwise the nanotube is a semiconductor.) Nanotube devices were made from NaDDBS wrapped micelle solutions of both kinds of tubes.

FIG. 7(a)(ii) depicts that for the HiPCO samples, after annealing, the gate dependence disappeared, indicating that the deposited tubes were mostly metallic. This is consistent with the higher dielectric constants expected for metallic tubes

FIGS. 7(b)(i)-(ii) show the I-V characteristics of a CoMoCAT SWNT device assembled across pointed electrodes configuration of FIG. 7(b)(iii). FIG. 7(b)(i) shows the drain-source curves measured at various gate voltages, whereas FIG. 7(b)(ii) shows the gate curve measured at V_{ds}=6.0 Volts. The gate curve shows that the tube displays ambipolar transport, indicative of a semiconducting tube. These semiconducting devices show gate dependence even after annealing.

The foregoing merely illustrates the principles of the invention. Various modifications and alterations to the described embodiments will be apparent to those skilled in the art in view of the teachings herein. It will thus be appreciated that those skilled in the art will be able to devise numerous systems and methods which, although not explicitly shown or described herein, embody the principles of the invention and are thus within the spirit and scope of the invention. For example, the inventors have also been able to align carbon nanotubes across deep pits by the methods described herein using the same procedures using Chromium electrodes and etching with a gaseous plasma. The tubes are suspended between two raised electrodes—as such the tubes are suspended between the electrodes in air. Moreover, although the aforementioned description was provided with respect to single-walled nanotubes, the methods and systems described herein are also applicable to multiwalled nanotubes.

What is claimed is:

1. A method of positioning carbon nanotubes on a substrate, the substrate including a first electrode and a second electrode thereon, the second electrode being positioned oppositely from the first electrode; the method comprising:
applying a first AC voltage across the first and second electrodes;
providing a first resistance in series with the first AC voltage; and
introducing a solution including at least one carbon nanotube;
wherein, when the first AC voltage is applied through the first resistance across the first and second electrodes, the at least one carbon nanotube attaches to the first and second electrodes.

2. The method of claim 1, the substrate including a third electrode and a fourth electrode thereon, the fourth electrode being positioned oppositely from the third electrode, the third electrode being positioned adjacent to the first electrode; wherein when the first AC voltage is applied across the first and second electrodes, the first AC voltage causes the third and fourth electrodes to have a floating potential.

3. The method of claim 2 further comprising:
removing the first AC voltage;
applying a second AC voltage to the third and fourth electrodes, the second AC voltage causing the first and second electrodes to have a floating potential; and
providing a second resistance in series with the second AC voltage;
wherein, when the second AC voltage is applied through the second resistance across the third and fourth electrodes, a second carbon nanotube attaches to the third and fourth electrodes.

4. The method of claim 2 wherein the substrate includes a metallic area thereon between the first and second electrodes, the metallic area being capable of perturbing an electric field formed by the first AC voltage source.

5. The method of claim 2 wherein the first and second electrodes include approximately pointed geometries.

6. The method of claim 5 wherein the third and fourth electrodes include approximately pointed geometries.

7. The method of claim 1 further comprising wrapping the at least one carbon nanotube in a micelle.

8. The method of claim 1 further comprising rinsing the substrate with deionized water.

9. The method of claim 1 further comprising drying the substrate in nitrogen.

10. The method of claim 1 wherein the voltage operates at a frequency of approximately 500 kHz to 20 MHz.

11. The method of claim 1 wherein the voltage is applied approximately between 1-600 seconds.

12. A system for positioning carbon nanotubes on a substrate, the substrate including a first electrode and a second electrode thereon, the second electrode being positioned oppositely from the first electrode; the system comprising:
a base for receiving the substrate;
a first AC voltage source coupled to the base, the first AC voltage source for applying a first AC voltage across the first and second electrodes; and
a first resistor coupled to the first AC voltage source to provide a first resistance in series with the first AC voltage source;
wherein, when the first AC voltage is applied through the first resistor across the first and second electrodes and a solution including at least one carbon nanotube is introduced on the substrate between the electrodes, the at least one carbon nanotube attaches to the first and second electrodes.

13. The system of claim 12, the substrate including a third electrode and a fourth electrode thereon, the fourth electrode being positioned oppositely from the third electrode, the third electrode being positioned adjacent to the first electrode; wherein when the first AC voltage is applied across the first and second electrodes, the first AC voltage causes the third and fourth electrodes to have a floating potential.

14. The system of claim 13 further comprising:
a second AC source coupled to the base, the second AC source for applying a second AC voltage to the third and fourth electrodes, the second AC voltage causing the first and second electrodes to have a floating potential; and
a second resistor coupled to the second AC source to provide a second resistance in series with the second AC voltage;
wherein, when the second AC voltage is applied through the second resistor across the third and fourth electrodes, a second carbon nanotube attaches to the third and fourth electrodes.

15. The system of claim 13 wherein the substrate includes a metallic area thereon between the first and second electrodes, the metallic area being capable of perturbing an electric field formed by the first AC voltage source.

16. The system of claim 13 wherein the first and second electrodes include approximately pointed geometries.

17. The system of claim 16 wherein the third and fourth electrodes include approximately pointed geometries.

18. The system of claim 12 further comprising a rinsor coupled to the body for rinsing the substrate with deionized water.

19. The system of claim 12 wherein the at least one carbon nanotube is wrapped in a micelle.

20. The system of claim 12 further comprising a drier coupled to the body for drying the substrate in nitrogen.

21. The system of claim 12 wherein the voltage operates at a frequency of approximately 500 kHz to 20 MHz.

22. The system of claim 12 wherein, the voltage is applied approximately between 1-600 seconds.

23. A circuit element coupled to a substrate, the substrate including a first electrode and a second electrode thereon, the second electrode being positioned oppositely from the first electrode; the circuit element being made by the process of
applying a first AC voltage across the first and second electrodes;
providing a first resistance in series with the first AC voltage; and
introducing a solution including at least one carbon nanotube;
wherein, when the first AC voltage is applied through the first resistance across the first and second electrodes, the at least one carbon nanotube attaches to the first and second electrodes.

24. The circuit element of claim 23, the substrate including a third electrode and a fourth electrode thereon, the fourth electrode being positioned oppositely from the third electrode, the third electrode being positioned adjacent to the first electrode; wherein when the first AC voltage is applied across the first and second electrodes, the first AC voltage causes the third and fourth electrodes to have a floating potential.

25. The circuit element of claim 24 wherein the process further comprises:
removing the first AC voltage;
applying a second AC voltage to the third and fourth electrodes, the second AC voltage causing the first and second electrodes to have a floating potential; and
providing a second resistance in series with the second AC voltage;
wherein, when the second AC voltage is applied through the second resistance across the third and fourth electrodes, a second carbon nanotube attaches to the third and fourth electrodes.

26. The circuit element of claim 24 wherein the substrate includes a metallic area thereon between the first and second electrodes, the metallic area being capable of perturbing an electric field formed by the first AC voltage source.

27. The circuit element of claim 24 wherein the first and second electrodes include approximately pointed geometries.

28. The circuit element of claim 27 wherein the third and fourth electrodes include approximately pointed geometries.

29. The circuit element of claim 23 wherein the process further comprises wrapping the at least one carbon nanotube in a micelle.

30. The circuit element of claim 23 wherein the process further comprises rinsing the substrate with deionized water.

31. The circuit element of claim 23 wherein the process further comprises drying the substrate in nitrogen.

32. The circuit element of claim 23 wherein the voltage operates at a frequency of approximately 500 kHz to 20 MHz.

33. The circuit element of claim 23 wherein the voltage is applied approximately between 1-600 seconds.
